(19) United States
(12) Patent Application Publication
(10) Pub. No.: US 2010/0207790 A1
(43) Pub. Date: Aug. 19, 2010

(54) ANALOG INPUT AND OUTPUT CIRCUIT AND VACUUM PROCESSING APPARATUS

(75) Inventors: Koji Toyota, Kudamatsu-shi (JP); Koichi Yamamoto, Hikari-shi (JP); Yuuzou Oohirabaru, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi High-Technologies Corporation

(21) Appl. No.: 12/396,574

(22) Filed: Mar. 3, 2009

(30) Foreign Application Priority Data
Feb. 16, 2009 (JP) 2009-032574

(51) Int. Cl. H03M 1/06

(52) U.S. Cl. 341/118

(57) ABSTRACT

The invention provides an analog input and output circuit and a vacuum processing apparatus capable of automatically performing the correction of all analog inputs and outputs via a single reference voltage adjustment, thereby solving the prior art problem of requiring a different correction value for each channel for accurately controlling the analog input and output due to the difference in the on resistances of switches for respective channels of an analog multiplexer. The prevent invention comprises an A/D converter 505 for converting an input analog signal into a digital signal; a D/A converter 506 for converting the digital signal into an analog signal; a computing unit for computing a first correction value 604 with respect to a digital signal of the input signal from the A/D converter and a second correction value 606 with respect to a digital signal output to the D/A converter using the first correction value; and a control unit for outputting control signals from the D/A converter 506 using the first correction value 610 and the second correction value 612.

The present application is based on and claims priority of Japanese patent application No. 2009-32574 filed on Feb. 16, 2009, the entire contents of which are hereby incorporated by reference.

### BACKGROUND OF THE INVENTION

1. Field of the Invention

The present invention relates to a vacuum processing apparatus for forming plasma in a vacuum reactor to process wafers, and specifically relates to an analog input and output circuit for performing analog input and analog output and a control unit having an analog input and output circuit.

2. Description of the Related Art

In a control operation of the above-mentioned type of vacuum processing apparatuses, analog signals and digital signals are mutually converted and used. Accurate A/D conversion and D/A conversion is indispensible to perform control without errors and malfunctions. Therefore, arts related to correcting the values of A/D conversion and D/A conversion are provided. Japanese patent application laid-open publication No. 2000-295102 (patent document 1) and No. 8-23275 (patent document 2) disclose methods for correcting A/D conversion and D/A conversion.

Further, the method disclosed in patent document 2 utilizes an A/D converter for correcting the D/A conversion. In a circuit having both an analog input device and an analog output device, it is possible to provide only a single A/D converter by using the A/D converter for correcting the D/A conversion also as the A/D converter for the analog input device. Japanese patent application laid-open publication No. 62-271103 (patent document 3) discloses a method of entering the analog output to the analog input in a loop and using the A/D converter for analog input also for correcting the D/A conversion.

Further, the cost of a deice will be increased significantly if A/D converters are arranged to correspond to the respective inputs of a deice having a plurality of analog inputs and having a plurality of devices connected thereto, such as a control unit. Therefore, it is possible to adopt a circuit configuration in which a plurality of analog signals entered from analog input ports are selected one by one via an analog multiplexer and output to a subsequent stage, where the plurality of analog inputs are subjected to A/D conversion via time division in a single A/D converter. Japanese patent application laid-open publication No. 2005-217870 (patent document 4) discloses a multichannel structure of an analog input device.

By combining several methods disclosed in the patent documents mentioned above, it is possible to obtain an analog input and output circuit capable of correcting A/D conversion and D/A conversion and also capable of processing multichannel inputs and outputs using only a single A/D converter.

The method for correction will be described below. At first, at least two voltages having predetermined values are entered to two or more channels of an analog multiplexer, and the values are selectively taken in one at a time, so as to subject a plurality of analog inputs to A/D conversion in a time-divisional manner using a single A/D converter. The respective conversion values are taken into the CPU, where they are compared with ideal conversion values obtained by subjecting the respective voltage values to A/D conversion, based on which the gain and offset correction parameters of A/D conversion are computed and stored in storage devices.

Next, the above-mentioned A/D conversion values are entered to an analog output stage, where they are converted via a D/A converter. The converted values are entered in a loop to an analog input stage, where they are subjected again to A/D conversion. At this time, in order to eliminate the error of A/D conversion, the correction parameters stored in the storage devices are used to perform correction computation of D/A conversion values, and the corrected values are compared with ideal values to compute the correction parameters of D/A conversion, which are stored in the storage devices.

However, the above-mentioned method has a drawback in that since there are differences in the on resistances of switches for respective channels of an analog multiplexer, in order to correct the analog input and output accurately, different correction values are required for the respective channels.

### SUMMARY OF THE INVENTION

The present invention aims at solving the problems of the prior art by providing an analog input and output circuit capable of automatically correcting all the analog inputs and outputs via a single reference voltage adjustment.

The outline of the present invention is as follows. According to the preferred embodiment of the present invention, the analog input and output circuit according to the present invention is used as an analog input and output section of a circuit on an input and output board connecting a module controller of a vacuum processing apparatus with respective control devices. The analog input and output circuit processes multichannel analog inputs and outputs, and is capable of correcting multichannel analog inputs and outputs, but the dispersion of on resistances of the analog multiplexer creates errors that differ per channel. In order to solve this problem, the analog input and output circuit of the present invention additionally provides a voltage follower between the analog multiplexer and the A/D converter.

The present invention provides an analog input and output circuit comprising an A/D converter for converting an input analog signal into a digital signal; a D/A converter for converting the digital signal into an analog signal; a computing unit for computing a first correction value with respect to a digital signal of the input signal from the A/D converter and a second correction value with respect to a digital signal output to the D/A converter using the first correction value; and a control unit for adjusting the signal output from the D/A converter using the first and second correction values.

Further, the present invention provides a vacuum processing apparatus for processing a sample within a vacuum reactor using plasma formed in the vacuum reactor, comprising an A/D converter for converting an input analog signal into a digital signal; a D/A converter for converting the digital signal into an analog signal; a computing unit for computing a first correction value with respect to a digital signal of the input signal from the A/D converter and a second correction value with respect to a digital signal output to the D/A converter using the first correction value; and a control unit for outputting a signal for adjusting the operation of the vacuum processing apparatus from the D/A converter.

According to the analog input and output circuit of the present invention, the correction of analog inputs and outputs can be performed promptly and accurately. According further to the vacuum processing apparatus of the present invention, the control signals for controlling the operation of the vacuum processing apparatus can be corrected promptly and accurately.

### BRIEF DESCRIPTION OF THE DRAWINGS

FIG. 1 is a view showing the configuration of a vacuum processing apparatus according to embodiment 1 of the present invention;

FIG. 2 is a view showing the configuration of communication of the apparatus according to embodiment 1;

FIG. 3 is a cross-sectional view of a process module according to embodiment 1;

FIG. 4 is a view showing the details of communication of the process module according to embodiment 1;

FIG. 5 is a block diagram showing the outline of configuration of the input and output board according to embodiment 1;

FIG. 6 is a block diagram showing the details of configuration of the analog input and output circuit, that is, the analog input and output section of the input and output board of FIG. 5 according to embodiment 2;

FIG. 7 is a flowchart showing the steps for correcting the analog input and output according to embodiment 2; and

FIG. 8 is a view showing an example of a conversion characteristic CAL1 of the A/D converter and an ideal conversion characteristic CAL0 according to embodiment 2.

### DETAILED DESCRIPTION OF THE PREFERRED EMBODIMENTS

Now, the preferred embodiments for carrying out the present invention will be described with reference to the drawings.

### Embodiment 1

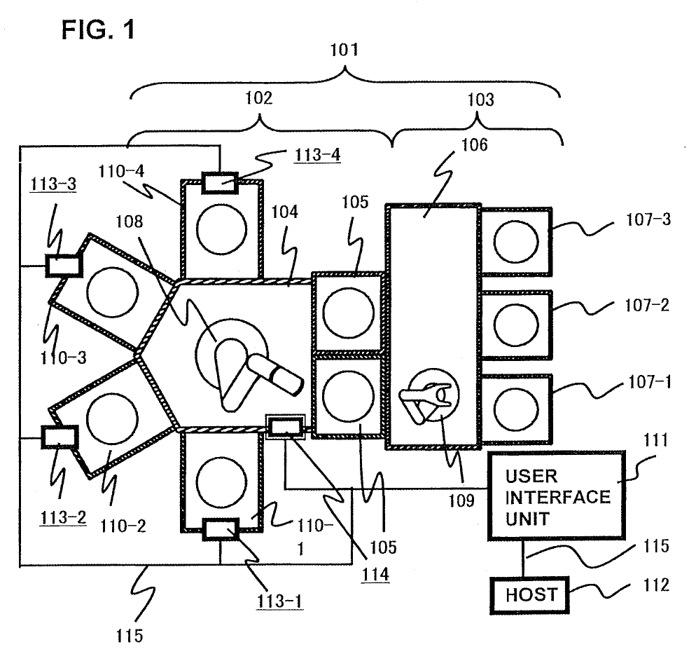

The vacuum processing apparatus of the present invention will be described with reference to FIGS. 1 through 5. FIG. 1 is a drawing showing the outline of the overall configuration of a vacuum processing apparatus according to a first embodiment of the present invention.

The vacuum processing apparatus illustrated in FIG. 1 can be largely divided into a transfer module 101 and process modules 110-1 through 110-4. The transfer module 101 is a module for transferring samples, which is composed of an atmospheric transfer unit 103 for transferring samples under atmospheric pressure, and a vacuum transfer unit 102 for carrying samples under a pressure decompressed from atmospheric pressure. The process modules 110-1 through 110-4 are modules such as for processing samples under vacuum pressure. The modules are respectively controlled via module controllers 113-1 through 113-4 and 114, which are connected to a user interface unit 111 and a host 112 via a signal line 115.

The atmospheric transfer unit 103 comprises a substantially rectangular housing 106 having an atmospheric transfer robot 109 disposed therein, and a plurality of cassette tables 107-1 through 107-3 attached to a front side (the right side in the drawing) of the housing 106 for mounting cassettes storing processing samples or cleaning samples.

The vacuum transfer unit 102 comprises a vacuum transfer vessel 104 having a substantially polygonal planar shape (pentagonal shape in the present embodiment), and two lock chambers 105 disposed between the vacuum transfer vessel 104 and the atmospheric transfer unit 103 for handing over samples between the atmospheric side and the vacuum side. The vacuum transfer unit 102 can be decompressed and maintained at a high vacuum pressure.

A vacuum transfer robot 108 is disposed at the center of a transfer chamber within the vacuum transfer vessel 104 for transferring samples under vacuum between the lock chambers 105 and processing chambers within process modules 110-1 through 110-4. Samples are placed on an arm of the vacuum transfer robot 108, and they are transferred between sample stages disposed in processing chambers of process modules 110-1 through 110-4 and sample stages within the lock chambers 105. Paths communicating the process modules 110-1 through 110-4, the lock chambers 105 and the transfer chamber within the vacuum transfer vessel 104 are opened and closed via valves capable of respectively opening and closing the paths in airtight manner.

The processing of a plurality of samples such as semiconductor samples stored in a cassette placed on one of the cassette tables 107-1 through 107-3 is started, based on the determination of a user interface unit 111 for controlling the operation of the vacuum processing apparatus, or based on the command from a host 112 or the like of the production line on which the vacuum processing apparatus is placed.

In the lock chamber 105, the valve is closed and sealed with the transferred sample stored therein, and the chamber is vacuumed to a predetermined pressure. Thereafter, the valve on the side facing the transfer chamber of the vacuum transfer vessel 104 is opened to communicate the lock chamber 105 and the transfer chamber, and the arm of the vacuum transfer robot 108 is extended into the lock chamber 105 to carry out the sample placed therein. The sample being placed on the arm of the vacuum transfer robot 108 is carried into one of the vacuumed processing chambers of the process modules 110-1 through 110-4 having been determined in advance when the sample is taken out of the cassette.

After the sample is carried into the processing chamber in one of the processing modules 110-1 through 110-4, the valve capable of opening and closing the path between the processing chamber and the transfer chamber is closed, and the processing chamber is sealed. Thereafter, processing gas is supplied into the processing chamber, by which a plasma is generated in the processing chamber to process the sample.

When it is detected that the processing of the sample has been completed, the valve is opened, and the vacuum transfer robot 108 carries out the sample to the lock chamber 105 in an opposite manner as when the sample was carried into the processing chamber. When the sample is carried into one of the lock chambers 105, the path communicating the lock chamber 105 and the transfer chamber is closed to seal the interior of the lock chamber, and the pressure within the lock chamber 105 is raised to atmospheric pressure.

Thereafter, the valve on the inner side of the housing 106 is opened to communicate the lock chamber 105 and the atmospheric transfer chamber within the atmospheric transfer vessel 106, and the sample is transferred via the atmospheric transfer robot 109 from the lock chamber 105 to the original cassette, where it is returned to the original position within the cassette.

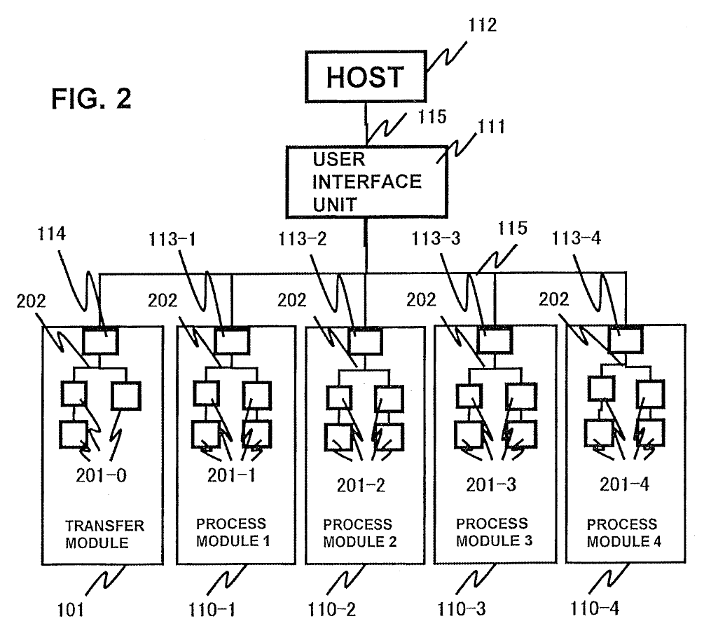

FIG. 2 is a block diagram showing in frame format the configuration of transmission and reception of signals for operating the vacuum processing apparatus of the present invention illustrated in FIG. 1.

A network is formed between the host 112, the user interface unit 111, the respective module controllers 113-1 through 113-4 and 114, and input and output boards 201-0 through 201-4, wherein the host 112, the user interface unit 111, the module controllers 113-1 through 113-4 and 114 are connected via signal line 115, and the module controllers 113-1 through 113-4 and 114 and the input and output boards 201-0 through 201-4 are connected via a signal line 202.

Here, the signal line 115 and the signal line 202 are connected via a similar LAN cable, but the signal line 115 performs communication via TCP/IP and the signal line 202 performs communication via PROFINET. In the present embodiment, the signal line 202 is described as communicating via PROFINET, but any type of network protocol capable of performing TCP/IP communication can be adopted.

The host 112 administers the semiconductor product line, and provides a command to start a process to the user interface unit 111. The user interface unit 111 is for manipulating the etching apparatus, equipped with a display means for displaying data such as a display, and an input means such as a keyboard and a mouse. Based on the command from the host 112, or based on operation of the user through the user interface unit 111, the user interface unit 111 notifies the starting of the etching process to the respective module controllers 113-1 through 113-4 and 114, and sends etching conditions and other data thereto.

Further, when a command to start the etching process and the data of the etching conditions are received from the user interface unit 111, the module controllers 113-1 through 113-4 generate control signals corresponding to the respective control devices, and sends the same to input and output boards 201-0 through 201-4 corresponding to the devices being controlled, and also notifies the monitor signals received from the input and output boards 201-0 through 201-4 to the user interface unit 111.

When the process is started by outputting a command to start the process from the host 112 or by the user operating the user interface unit 111, the user interface unit 111 commands the transfer of a sample to the module controller 114 of the transfer module 101, and the process module 110-1 through 110-4 to be used for processing the sample. Further, the etching condition data is sent to the module controllers 113-1, 113-2, 113-3 or 113-4 of the process modules 110-1, 110-2, 110-3 or 110-4 for processing the sample.

The module controller 114 of the transfer module 101 controls the atmospheric transfer unit 103 and the vacuum transfer unit 102, and transfers the sample to one of the process modules 110-1 through 110-4 designated by the user interface unit 111.

After completing the transfer of the sample to the process modules 110-1 through 110-4, the module controllers 113-1 through 113-4 corresponding to the process modules send control signals for respective control devices to the input and output boards 201-0 through 201-4 according to etching conditions received from the user interface unit 111.

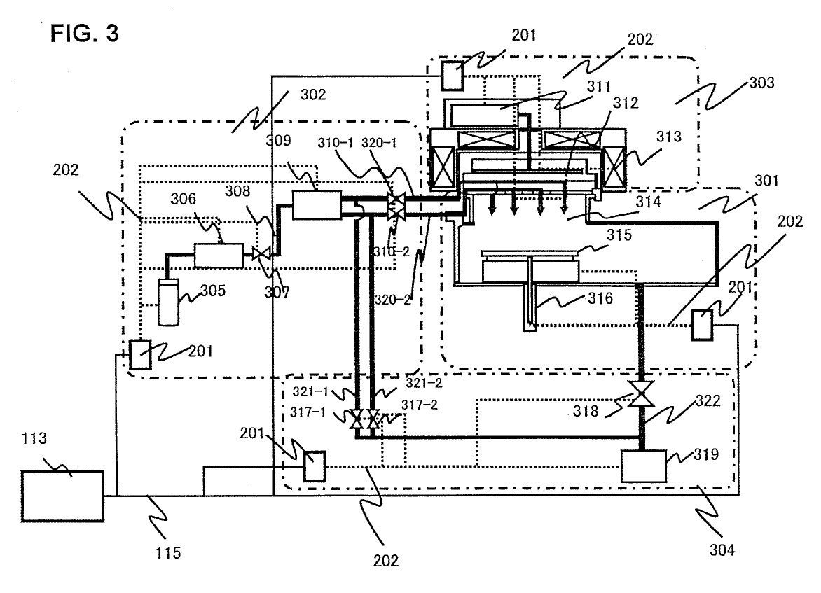

The input and output boards 201-0 through 201-4 convert the received control signals to voltage values, and send the same to the control devices. FIG. 3 is a cross-sectional view showing the configuration of process modules 110-1 through 110-4 of the embodiment illustrated in FIG. 1 from the side. Especially, the present drawing illustrates the configuration of some of the process modules 110-1 through 110-4 arranged on the rear side of the vacuum transfer vessel 104 (on the left side in FIG. 1), and in the present embodiment, the two process modules 110 arranged on the rear side are etching modules for etching the surface of samples using plasma.

In the present drawing, the process module 110 comprises a vacuum reactor unit 301, a gas supply unit 302, a plasma generating unit 303 disposed on the upper portion of the vacuum reactor 301, and an evacuation unit 304 disposed below the vacuum reactor 301.

The vacuum reactor unit 301 comprises a processing chamber 314 for processing the sample therein, a sample stage 315 for placing the sample, and a drive mechanism 316 for moving the sample stage 315 up and down, wherein the plasma generated via the plasma generating unit 303 and the gas supply unit 302 is used to subject the sample to etching process.

The gas supply unit 302 is composed of a gas supply source 305, a flow rate controller 306 for maintaining a constant gas flow rate, a valve 307 for shutting the gas flow from the gas supply source 305, a gas supply line 308 for flowing gas from the gas supply source, a shunt 309 for dividing the gas supply line 308 into two lines, gas lines 320-1 and 320-2 for gas flow shunted into two lines via the shunt 309, and valves 310-1 and 310-2 for shutting the gas flowing through the gas lines 320-1 and 320-2, wherein during the etching process, the flow rate is set in the flow rate controller 306 and the shunt rate is set in the shunt 309, and the process gas is introduced through a first gas supply line 320-1 and a second gas supply line 320-2 into the processing chamber 314.

The plasma generating unit 303 is composed of a microwave plasma generation source 311, an antenna 312 for introducing microwaves, and solenoid coils 313 for generating magnetic field, wherein the microwaves supplied via the antenna 312 and the magnetic field generated by the solenoid coils 313 operate to provide energy to the gas introduced from the gas supply unit 312, by which plasma is formed.

The evacuation unit 304 is composed of evacuation lines 321-1 and 321-2 for evacuating the gas lines 320-1 and 320-2, valves 317-1 and 317-2 for shutting the evacuation lines 321-1 and 321-2, a processing chamber evacuation line 322 for evacuating the processing chamber 314, a processing chamber evacuation valve 318 for shutting the processing chamber evacuation line 322, and an evacuation pump 319, wherein by activating the evacuation pump 319, the evacuation valves 317-1 and 317-2 and the processing chamber evacuation valve 138, it becomes possible to bring the gas lines 320-1 and 320-2 and the processing chamber 314 to a vacuum state.

The operation of respective components constituting the above units is controlled via the voltage value converted from control signals via the input and output boards 201-0 through 201-4 arranged in correspondence to the units.

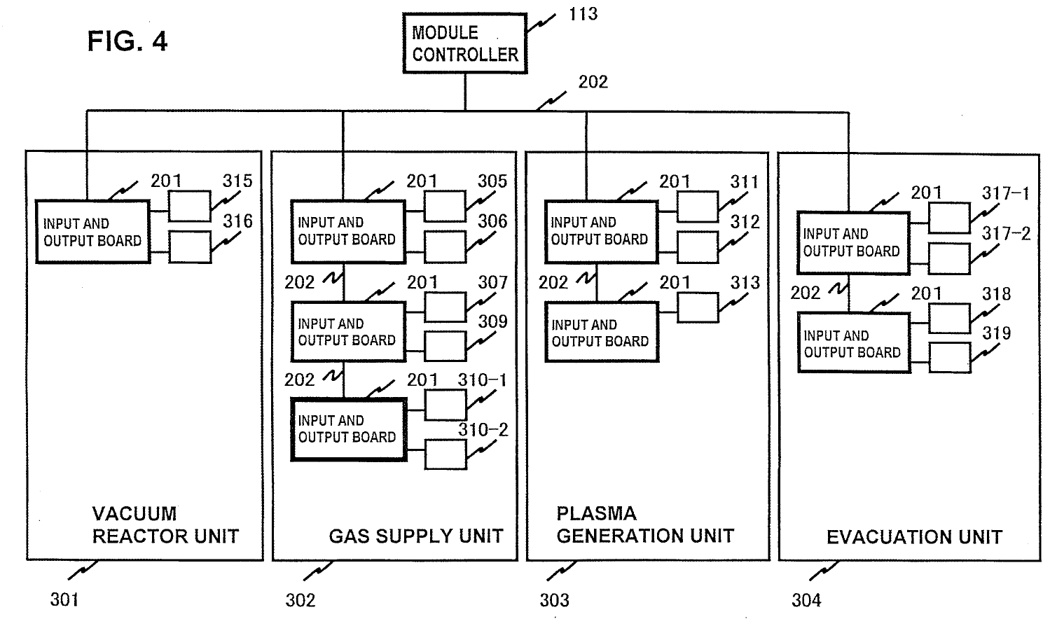

Next, we will describe the details of the transmission and reception of control signals within the module and the details of the present invention with reference to FIG. 4. FIG. 4 is a view showing in detail the configuration of the transmission and reception of control signals in the process module illustrated in FIG. 3.

As described, the vacuum reactor unit 301, the gas supply unit 302, the plasma generating unit 303 and the evacuation unit 304 are controlled via module controllers 113-1 through 113-4. Further, each unit includes a plurality of devices being controlled, and in order to send signals to the devices being controlled, input and output boards 201 are arranged between the module controllers 113-1 through 113-4 and the devices being controlled.

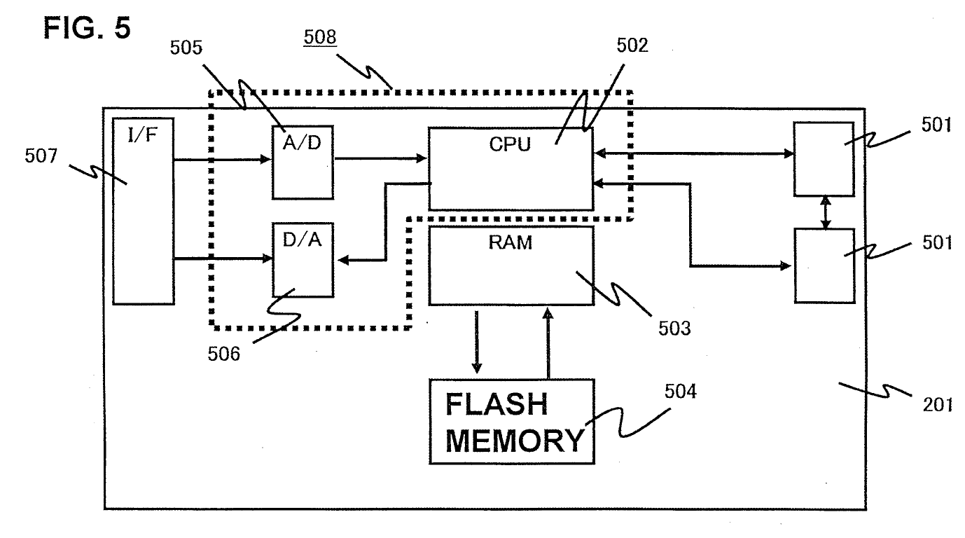

Next, we will describe the configuration of the input and output board 201 with reference to FIG. 5. FIG. 5 is a block diagram showing the outline of the structure of the input and output board 201.

The input and output board 201 includes at least two LAN ports 501 having switching functions, a CPU 502, a RAM 503, a nonvolatile memory 504 such as a flash memory, an A/D converter 505 for converting voltage values into monitor signals, a D/A converter 506 for converting the control signals into voltage values, and a communication interface 507 for communicating with the control devices.

The CPU 502 converts control signals received from the LAN port 501 into voltage values using the D/A converter 506 based on a conversion rule retained in advance, and sends the same via the communication interface 507 to control devices.

Further, the voltage values reported from the control devices via the communication interface 507 are converted into monitor signals using the A/D converter 505, which are then sent via the LAN port 501 to module controllers 113-1 through 113-4.

### Embodiment 2

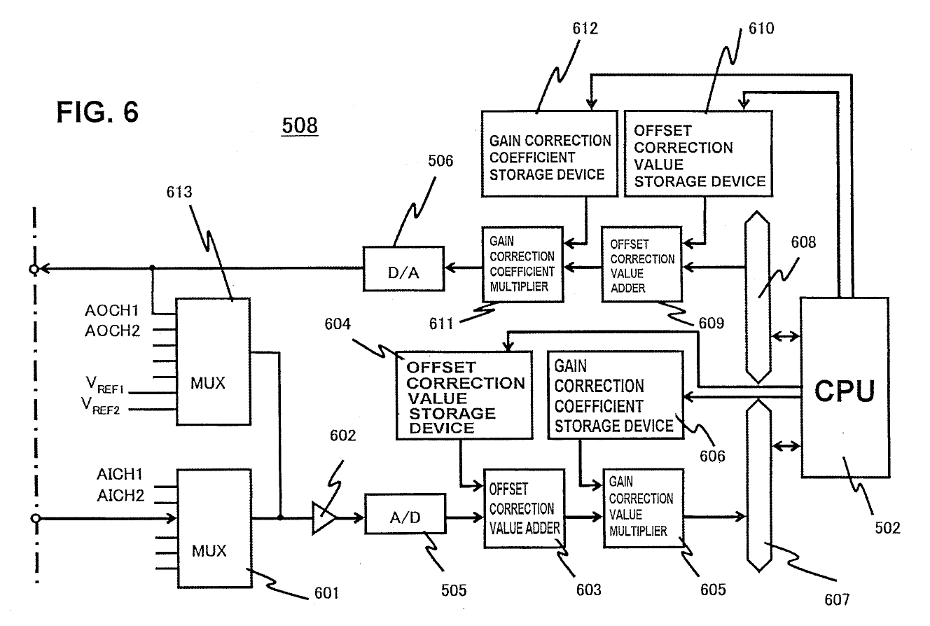

Next, we will describe the configuration of an analog input and output circuit 508 according to embodiment 2 of the present invention with reference to FIG. 6. FIG. 6 is a block diagram showing the detailed configuration of the analog input and output circuit.

In FIG. 6, the analog input and output circuit 508 includes an analog multiplexer 601 for selecting and taking in one of the analog inputs from a plurality of channels, a voltage follower 602, an A/D converter 505, an offset correction value adder 603 for performing offset correction of the A/D conversion value, an offset correction value storage device 604 for storing the offset correction value and entering the same to the adder 603, again correction coefficient multiplier 605 for performing gain correction of the A/D conversion value, a gain correction coefficient storage device 606 for storing the gain correction coefficient and entering the same to the multiplier 605, and a data bus 607 connected to the CPU 502.

Further, the analog input and output circuit 508 includes a data bus 608 connected to the CPU 502, an offset correction coefficient adder 609 for performing offset correction of the digital signals to be entered to the D/A converter, an offset correction coefficient storage device 610 for storing the offset correction coefficient and entering the same to the adder 609, a gain correction coefficient multiplier 611 for performing gain correction of the digital signals entered to the D/A converter, a gain correction coefficient storage device 612 for storing the gain correction coefficient and entering the same to the adder 611, a D/A converter 506, and an analog multiplexer 613 for selecting one analog output voltage of a plurality of channels or selecting one of at least two reference voltages for correction and entering the same to the analog input side. The voltage follower 602 is for minimizing the influence of dispersion of on resistances of the analog multiplexers 601 and 613 to a negligible level.

The analog input voltage of a plurality of channels entered via the analog input port is entered to respective channels (AICH1, AICH2 and so on) of the analog multiplexer 601, and handed over one by one in a time divisional manner to the A/D converter 505 via the voltage follower 602. At this time, the offset correction value adder 603 adds the digital signal from the A/D converter 505 and the offset correction value from the offset correction value storage device 604, and the digital signal representing the added result is output to the gain correction coefficient multiplier 605. The gain correction coefficient multiplier 605 multiplies the digital signal from the offset correction value adder 603 by the gain correction coefficient from the gain correction coefficient storage device 606, and the digital signal representing the multiplied result is output to the data bus 607. The digital signal output to the data bus 607 is taken into the CPU 502 and processed.

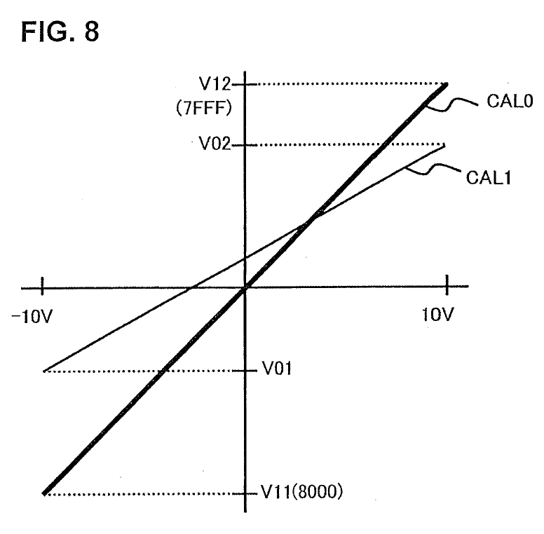

Now, we will explain the method for computing the offset correction value and the gain correction coefficient with reference to FIG. 8. FIG. 8 is a view showing a conversion characteristic CAL0 of an ideal A/D converter and a conversion characteristic CAL1 of the actual A/D converter. In other words, the A/D converter of FIG. 6 shows the conversion characteristic CAL1 as shown in FIG. 8. Therefore, the offset correction value and the gain correction coefficient are computed based on the conversion characteristic CAL0 of the ideal A/D converter as shown by the heavy line of FIG. 8 and the conversion characteristic CAL1 of the actual A/D converter, which are used to convert the digital signal output from the A/D converter 505 to a digital signal corresponding to the conversion characteristic CAL0 of the ideal A/D converter shown by the heavy line of FIG. 8.

The conversion characteristic CAL0 of the ideal A/D converter shown in FIG. 8 outputs a digital signal of a predetermined value V12 (7FFF in hexadecimal display) in response to the input of analog signal voltage 10 [V] in a plus full scale, and outputs a digital signal of a predetermined value V11 (8000 in hexadecimal display) in response to the input of analog signal voltage −10 [V] in a minus full scale. However, the actual A/D converter 505 outputs a digital signal composed of output digital value V02 that differs from the ideal value V12 with respect to the input of analog signal voltage 10 [V], and outputs a digital signal composed of output digital value V01 that differs from the ideal value V12 with respect to the input of analog signal voltage −10 [V].

Therefore, according to the present embodiment, if two reference analog input voltages are used, the predetermined first reference analog input voltage is entered to the A/D converter 505, and the conversion value (V01) output in response thereto is taken into the CPU 502. Next, a predetermined second reference analog input voltage (that differs from the first reference analog input voltage) is entered to the A/D converter 505, and the conversion value (V02) output in response thereto is taken into the CPU 502. After taking in digital signals V01 and V02, the CPU computes the offset correction value and the gain correction coefficient.

When the offset correction value is represented by DO and the gain correction coefficient is represented by DG, the following arithmetic expressions (1) and (2) can be obtained.

DO=(V02+V01)/2 (1)

DG=(V12−V11)/(V02−V01) (2)

The offset correction value and the gain correction coefficient are respectively stored in the offset correction value storage device 604 and the gain correction coefficient storage device 606 shown in FIG. 6, and during the A/D conversion performed thereafter, the output from the storage devices 604 and 606 are entered as correction parameters to the offset correction value adder 603 and the gain correction coefficient multiplier 605, so as to automatically correct the A/D conversion value.

In the actual conversion, the resistances of the switches differ for switching on and off the respective channels of the analog multiplexer 601 for selectively taking in one of the multichannel analog input voltages. Therefore, according to the present embodiment, by arranging a voltage follower 602 between the analog multiplexer 601 and the A/D converter 505, the influence of dispersion of on resistances can be minimized to a negligible level.

In general, the on resistance of an analog multiplexer is approximately tens to a few hundred Ω, and the dispersion between channels is approximately a few to over ten Ω. For example, in the case of an analog multiplexer ADG1206 manufactured by Analog Devices, Inc., the on resistance is 120 to 126Ω in room temperature. Generally, the input impedance of a voltage follower is extremely high compared thereto, reaching approximately 100 kΩ to a few TΩ. For example, in the case of a voltage follower using an operation amplifier ADA4000-4 manufactured by Analog Devices, Inc., the input impedance is approximately 10 GΩ.

The following is an example of performing A/D conversion using an analog input voltage of 10 V, an analog multiplexer ADG1206, and an operational amplifier ADA4000-4 constituting a voltage follower. If the on resistance of the analog multiplexer ADG1206 is 120Ω or 126Ω, the synthetic impedance of the former case will be 120+10⁹Ω=10000000120Ω, whereas the synthetic impedance of the latter case will be 126+10⁹Ω=10000000126Ω. If the same analog input voltage of 10 V is applied in the former and latter cases, the voltage entered to the voltage follower will be 9.99999880000014×10⁻⁹ V in the former case and 9.99999876500015×10⁻⁹ V in the latter case.

Since the size of the input and output of the voltage follower is equal, the above voltage value will be the voltage to be actually entered to the A/D converter. Now, for example, the minimum bit for converting an analog input of plus or minus 10 V using an A/D converter having a 16-bit resolution is 3.05175781250000×10⁻⁴ V. Further, the difference between the above-mentioned two voltage values is 3.49999919875051×10⁻⁹ V, which is approximately five digits smaller than the minimum bit, and therefore, it is negligible.

As described, by arranging a voltage follower 602 having a high input impedance between the analog multiplexer 601 and the A/D converter 505, it becomes possible to minimize the influence of dispersion of the on resistances to a negligible level.

Further, the D/A conversion is corrected in a similar manner as the A/D conversion. An offset correction value adder 609 shown in FIG. 6 adds the digital signal sent via the data bus 608 from the CPU 502 and the offset correction value from an offset correction value storage device 610, and outputs the digital signal of the added result to a gain correction coefficient multiplier 611. The gain correction coefficient multiplier 611 multiplies the digital signal from the offset correction value adder 609 by a gain correction coefficient from a gain correction coefficient storage device 612, and outputs the digital signal corresponding to the multiplied result to a D/A converter 506.

Further, the analog signal output from the D/A converter 506 is entered in a loop to the A/D converter 505 via an analog multiplexer 613 a voltage follower 602 for minimizing the influence of dispersion of on resistances to a negligible level, which are converted into digital signals and sent to the CPU 502 as feedback. This operation is for computing the offset correction value and the gain correction coefficient of the D/A converter 506, and the respective correction parameters can be computed in a similar manner as described heretofore.

At first, a first reference digital signal voltage is supplied to the offset correction value adder 609, and the digital conversion value of the analog signal output from the D/A converter 506 is taken in. Next, a second reference digital signal voltage is supplied to the offset correction value adder 609, and the digital conversion value of the analog signal output from the D/A converter 506 is taken in. At the point of time where the two digital signals have been entered, the CPU 502 computes the offset correction value and the gain correction coefficient, and stores the same in the offset correction value storage device 610 and the gain correction coefficient storage device 612.

When the offset correction value is referred to as Do, the gain correction coefficient is referred to as Dg, the reference digital signals are referred to as D1 and D2, and the converted values thereof are referred to as V1 and V2, the following arithmetic expressions can be obtained.

Do=(V2+V1)/2 (3)

Dg=(D2−D1)/(V2−V1) (4)

The offset correction value and the gain correction coefficient are respectively stored in the offset correction value storage device 610 and the gain correction coefficient storage device 612, and when performing D/A conversion thereafter, the outputs from the storage devices 610 and 612 are entered as correction parameters to the offset correction value adder 609 and the gain correction coefficient multiplier 611, by which the D/A conversion value is automatically corrected.

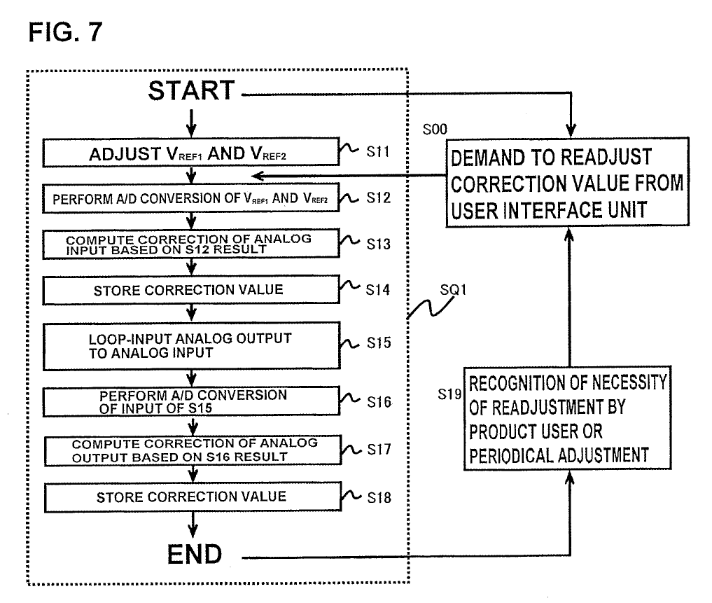

Further, since an A/D converter 505 is used to correct the D/A converter 506, the conversion value of the A/D converter 505 must be accurate. In other words, the correction parameters of the A/D converter 505 must be stored in the respective storage devices 604 and 605 prior to performing correction of D/A conversion. An example of the process for correcting the overall analog input and output will be described with reference to FIG. 7. FIG. 7 is a flowchart illustrating the steps for correcting the analog input and output.

At first, in step S11, reference analog input voltages V_{REF1} AND V_{REF2} (two values are adopted in the example) are adjusted. The error with respect to the predetermined reference voltage should at least be smaller than LSB/2 of the resolution of the A/D converter and the D/A converter. For example, if a voltage of plus or minus 10 V is to be converted via a converter having a 16-bit resolution, the LSB equals 3.05175781250000×10⁻⁴ V, so the voltage should approximately be within the range of plus or minus 0.15 mV from the reference voltage.

Next, in step S12, the reference analog input voltages V_{REF1} AND V_{REF2} are sequentially entered via the analog multiplexer 613 and the voltage follower 602 to the A/D converter 505 for conversion. Next, instep S13, the converted values are entered to the CPU 502, where they are compared with the ideal converted values according to the respective reference analog input values, so as to compute the gain and the offset correction parameters of the A/D conversion, and in step S14, the values are stored in the respective storage units 603 and 605.

At this time, the respective conversion values entered to the CPU 502 are handed over via the data bus 608 to an analog output stage, and converted to analog voltage via the D/A converter 506. In step S15, the analog voltage is entered via loop input to an analog input stage, where it is subjected to A/D conversion in the A/D converter 505.

In step S16, in order to eliminate the error of A/D conversion, the A/D conversion value is subjected to correction computation by entering the respective correction parameters stored in the storage devices 603 and 605 to the offset correction value adder 603 and the gain correction coefficient multiplier 605. In step S17, the values are compared with the ideal values, so as to compute the gain and offset correction parameters of the D/A conversion, and in step S18, the computed values are stored in the storage devices 610 and 612.

The above-mentioned correction process sequence SQ1 (steps S11 through S16) is a correction to be performed after manufacturing the analog input and output circuit and before releasing the same as product. At this time, after performing the correction once, the analog input and output will always be corrected automatically according to the stored correction values. Therefore, the storage devices 603, 605, 610 and 612 should retain their memory even after cutting power, and from the viewpoint of cost and space, nonvolatile memories such as flash memories are selected.

Even after releasing the product, in step S00, it is possible to access the CPU 502 by manipulating the user interface unit 111, so as to perform the sequence SQ1 again via a program created in advance in the CPU 502.

Thereafter, correction parameters of the analog input and output are computed in a similar manner and stored in storage devices 603, 605, 610 and 612. Thereafter, correction is performed automatically during A/D conversion and D/A conversion, but as shown in step S19, if it is recognized that the conversion characteristics have changed due for example to variability with time or by the change of environment, or if the user wishes to maintain the correction parameters to optimal values constantly to prevent such changes in conversion characteristics, step S00 can be performed many times to update the respective correction parameters.

Though not shown in the analog input and output circuit configuration of FIG. 6, it is necessary to provide a timing to switch input channels to the analog multiplexers 601 and 613, so a timing signal created in the CPU 502 is entered.

Similarly, by providing an enable signal to order the analog multiplexer 613 to be activated or stopped via the CPU 502, it becomes possible to re-compute the correction parameters. At this time, by manipulating the user interface unit 111 to access the CPU 502 and to order the analog multiplexer 613 to be activated or stopped, it becomes possible to re-compute the correction parameters without manipulating the board (analog input and output circuit) directly.

What is claimed is:

1. An analog input and output circuit comprising:
an A/D converter for converting an input analog signal into a digital signal;
a D/A converter for converting the digital signal into an analog signal;
a computing unit for computing a first correction value with respect to a digital signal of the input signal from the A/D converter and a second correction value with respect to a digital signal output to the D/A converter using the first correction value; and
a control unit for adjusting the signal output from the D/A converter using the first and second correction values.

2. The analog input and output circuit according to claim 1, wherein the first and second correction values are correction values regarding a gain and an offset.

3. The analog input and output circuit according to claim 1, further comprising a first and a second storage unit for storing the first and second correction values.

4. The analog input and output circuit according to claim 1, further comprising a plurality of input analog signals in the control unit, and a selector for selecting one of the plurality of input analog signals.

5. The analog input and output circuit according to claim 1, further comprising a buffer of high input impedance arranged after the selector of the control unit and before the A/D converter.

6. The analog input and output circuit according to claim 1, further comprising an operating means connected either directly or indirectly to the control unit, wherein the correction process can be performed through the operating means without operating the control unit directly.

7. A vacuum processing apparatus for processing a sample within a vacuum reactor using plasma formed in the vacuum reactor, comprising:
an A/D converter for converting an input analog signal into a digital signal;
a D/A converter for converting the digital signal into an analog signal;
a computing unit for computing a first correction value with respect to a digital signal of the input signal from the A/D converter and a second correction value with respect to a digital signal output to the D/A converter using the first correction value; and
a control unit for outputting a signal for adjusting the operation of the vacuum processing apparatus from the D/A converter.

8. The vacuum processing apparatus according to claim 7, wherein the first and second correction values are correction values regarding a gain and an offset.

9. The vacuum processing apparatus according to claim 7, further comprising a first and a second storage unit for storing the first and second correction values.

10. The vacuum processing apparatus according to claim 7, further comprising a plurality of input analog signals in the control unit, and a selector for selecting one of the plurality of input analog signals.

11. The vacuum processing apparatus according to claim 7, further comprising a buffer of high input impedance arranged after the selector of the control unit and before the A/D converter.

12. The vacuum processing apparatus according to claim 7, further comprising an operating means connected either directly or indirectly to the control unit, wherein the correction process can be performed through the operating means without operating the control unit directly.
